(19) United States
(12) Patent Application Publication
(10) Pub. No.: US 2014/0284633 A1
(43) Pub. Date: Sep. 25, 2014

(54) STACKED LIGHT EMITTING DIODE ARRAY STRUCTURE

(71) Applicant: MIRACLE TECHNOLOGY CO., Hsinchu County (TW)

(72) Inventors: WEN CHIN TSAY, HSINCHU COUNTY (TW); LI-HUNG LAI, HSINCHU COUNTY (TW)

(73) Assignee: MIRACLE TECHNOLOGY CO., Hsinchu County (TW)

(21) Appl. No.: 14/222,819

(22) Filed: Mar. 24, 2014

(30) Foreign Application Priority Data
Mar. 25, 2013 (TW) 102110508

(51) Int. Cl. H01L 25/075

(52) U.S. Cl. CPC H01L 25/0756
USPC 257/88

(57) ABSTRACT

The present invention provides a stacked LED array structure, comprising a substrate and a plurality of LED dies stacked on the substrate in turn. Each LED die comprises a first semiconductor layer and a second semiconductor layer. The first semiconductor layer is provided thereon with a first electrode and stacked with the second semiconductor layer, while the second semiconductor layer is provided thereon with a second electrode and stacked with the first semiconductor layer of another LED die. The second electrode of each LED die is connected to the first electrode of another LED die in series via a metal layer to from an LED array. A plurality of LED dies may be stacked to be an LED array in a stacked manner, resulting in not only easy manufacturing, but also an effectively reduced volume for arranging the whole LED array.

### FIELD OF THE INVENTION

The present invention is related to a light emitting diode array structure, particularly to a stacked light emitting diode array structure.

### BACKGROUND

A light emitting diode (LED) is a semiconductor light emitting device, which is electroluminescent when forward bias is applied thereon. The recent LED has been developed to be operated with high-voltage alternating-current power supply (such as AC 110V/220V, for example). Furthermore, the merits of low power consumption and long service life, compared with the electric lamp bulb (such as incandescent lamp, for example) or fluorescent tube (such as fluorescent lamp, for example), are provided for the LED. Therefore, the LED is used for illumination, instead of the electric lamp bulb or fluorescent tube, gradually.

When the LED is applied to illumination, it is generally to connect a plurality of LEDs in series as an array, in such a way that the plurality of LEDs are used for luminescence, so as to obtain a wide luminescence region.

Referring to FIG. 1, there is shown a structural diagram of a conventional LED array structure. As illustrated in the figure, a single substrate 11 is provided laterally thereon with a plurality of LED dies 13, spaced from each other by a certain distance. Furthermore, a first electrode 131 of each LED die 13 is connected to a second electrode 132 of another adjacent LED die 13 by means of a metal wire 15, as well as the first electrode 131 of the leftmost LED die 13 is connected to a first potential pad 111 of the substrate 11 by means of the metal wire 15, and the second electrode 132 of the rightmost LED die 13 is connected to a second potential pad 113 of the substrate 11 by the metal wire 15. In this case, these LED dies 13 may be connected in series to be an LED array 100 by means of electrical connection of the metal wire 15.

In the conventional LED array 100, however, the LED dies 13 may be only arranged in a limited lateral space, leading to incapability of providing more LED dies 13 in a predetermined space. Thus, it is often incapable of enhancing luminescence intensity effectively.

Alternatively, referring to FIG. 2, there is shown a structural diagram of another conventional LED array structure. As illustrated in the figure, an LED array 200 comprises a substrate 21 and a plurality of LED devices 23. Each of these LED devices 23 is a packaged electronic device, respectively. Each LED device 23 is stackedly provided on the substrate 21 in a vertical direction, with a transparent plate 25 interposed between the LED devices 23, respectively. In this connection, a first electrode 231 of the lowermost LED device 23 is connected to a first potential pad 211 of the substrate 21 by means of a metal wire 27, while a second electrode 233 of the uppermost LED device 23 is connected to a second potential pad 213 of the substrate 21 by means of the metal wire 27, as well as the first electrode 231 of each LED device 23 is connected to the second electrode 233 of another LED device by means of the metal wire 27. In this case, these LED devices 23 may be connected in series to be another LED array 200 by means of electrical connection of the metal wire 27.

In the another conventional LED array 200, each LED device 23 is arranged in a stacked manner. Although the number of LED devices 23 provided in a predetermined space may be adjusted easily, each packaged LED device 23 should be used in the LED array 200 as a fundamental component, also resulting in an increased cost in package and whole volume, correspondingly.

### SUMMARY OF THE INVENTION

It is one object of the present invention to provide a stacked LED array structure, in which a plurality of LED dies are stacked vertically upward to be an LED array in a stacked manner, in such a way that more LED dies may be provided in a space.

It is one object of the present invention to provide a stacked LED array structure, the manufacturing process of which includes depositing semiconductor materials for manufacturing a plurality of LED dies on a substrate directly, so as to form an LED array on the substrate, in such a way that not only the LED array may be manufactured easily, but also the volume for providing the whole LED array may be reduced effectively.

It is one object of the present invention to provide a stacked LED array structure, allowed for providing a plurality of sets of stacked LED arrays on a substrate laterally, so as to further obtain a wider luminescence region together with enhanced luminescence intensity in the region.

It is one object of the present invention to provide a stacked LED array structure. in which a stacked LED array is provided on a substrate in a flip-chip manner.

To achieve above objects, the present invention provides a stacked LED array structure, comprising: a substrate, provided on a surface thereof with a first potential pad and a second potential pad; a plurality of LED dies, stacked on the substrate in turn, each of the LED dies, respectively, comprising: a first semiconductor layer; and a second semiconductor layer, in which a top surface of the first semiconductor layer is provided with a first electrode and stacked with the second semiconductor layer, while a top surface of the second semiconductor layer is provided with a second electrode and/or stacked with the first semiconductor layer of another LED die; and at least one metal layer, in which the second electrode of each of the LED dies is connected to the first electrode of another LED die in series via the corresponding metal layer to be an LED array; wherein the first electrode of the first semiconductor layer stacked lowermost is connected to the first potential pad of the substrate via a metal wire, while the second electrode of the second semiconductor layer stacked uppermost is connected to the second potential pad of the substrate via another metal wire.

The present invention another provides a stacked LED array structure, comprising: a substrate, provided on a surface thereof with a first potential pad and a second potential pad; a plurality of LED dies, stacked on a base in turn, each of the LED dies, respectively, comprising: a first semiconductor layer; and a second semiconductor layer, in which a top surface of the first semiconductor layer is provided with a first electrode and stacked with the second semiconductor layer, while a top surface of the second semiconductor layer is provided with a second electrode and/or stacked with a first semiconductor layer of another LED die; and at least one metal layer, in which the second electrode of each of the LED dies is connected to the first electrode of another LED die in series via the corresponding metal layer to be an LED array; wherein the LED array is provided on the substrate in a flip-chip manner, such that the first electrode of the first semiconductor layer stacked lowermost is connected to the first potential pad of the substrate, while the second electrode of the second semiconductor layer stacked uppermost is connected to the second potential pad of the substrate.

In one embodiment of the present invention, wherein the first semiconductor layer is an N-type semiconductor layer, while the second semiconductor layer is a P-type semiconductor layer.

In one embodiment of the present invention, wherein the substrate is provided laterally thereon with a plurality of sets of the stacked LED arrays.

### BRIEF DESCRIPTION OF DRAWINGS

FIG. 1 is a structural diagram of a conventional LED array structure.

FIG. 2 is a structural diagram of another conventional LED array structure.

FIG. 3 is a structural diagram of a stacked LED array structure according to one preferred embodiment of the present invention.

FIGS. 4A to 4B are structural diagrams illustrating the manufacturing process of a stacked LED array structure according to a further embodiment of the present invention.

FIG. 5 is a structural diagram of a stacked LED array structure according to a further embodiment of the present invention.

FIG. 6 is a structural diagram of a stacked LED array structure according to a further embodiment of the present invention.

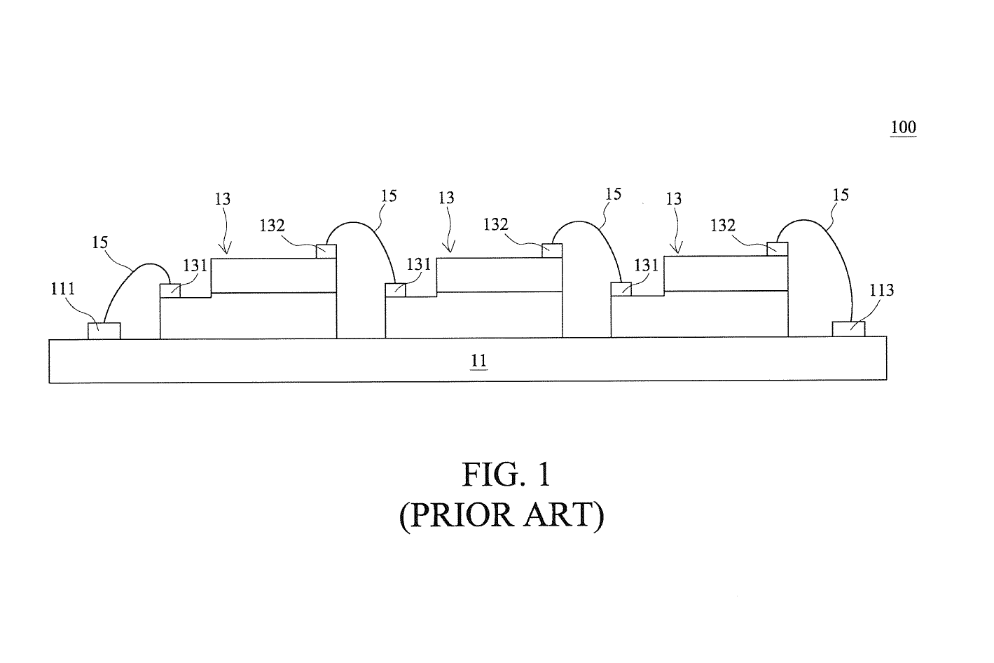

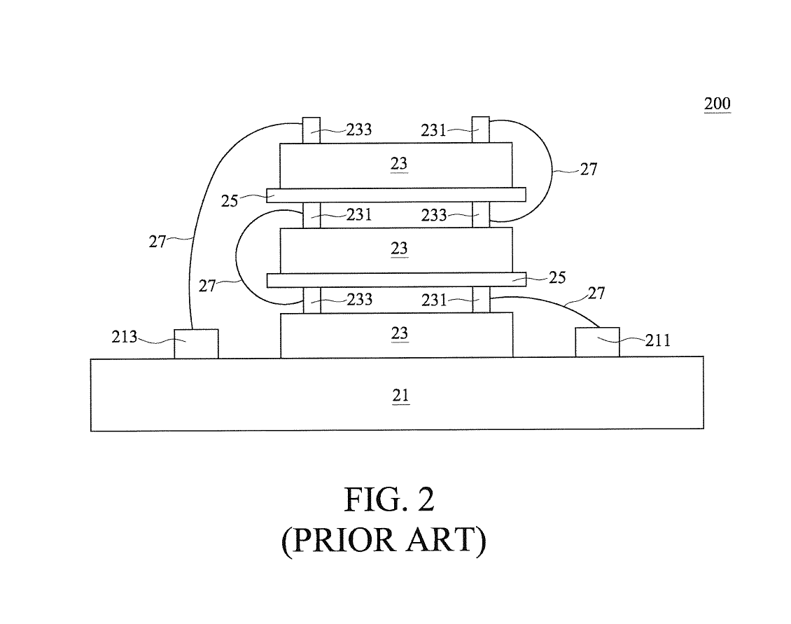

### DETAILED DESCRIPTION

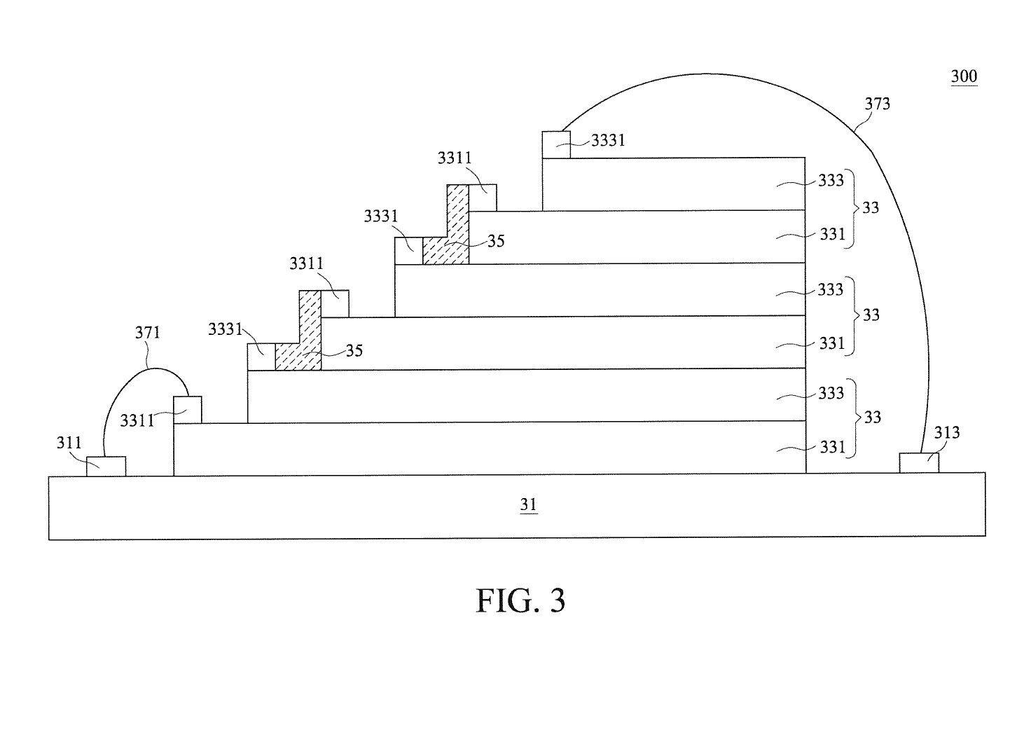

Referring to FIG. 3, there is shown a structural diagram of a stacked LED array structure according to one preferred embodiment of the present invention. As illustrated in the figure, an LED array 300 comprises a substrate 31 and a plurality of LED dies 33.

Each LED die 33, is stacked on the substrate 31 in turn, comprises a first semiconductor layer 331 and a second semiconductor layer 333, respectively. The first semiconductor layer 331 is an N-type semiconductor layer, while the second semiconductor. layer 333 is a P-type semiconductor layer.

When the deposition process is used, the second semiconductor layer 333 may be depositingly stacked on a part of surface of the first semiconductor layer 331 in each LED die 33, as well as the first semiconductor layer 331 of each LED die 33 may be depositingly stacked on a part of surface of the substrate 31 or a part of surface of the second semiconductor layer 333 of another LED die 33. Furthermore, the exposed surface at one side of the first semiconductor layer 331 is provided with a first electrode 3311, while the exposed surface at one side of the second semiconductor layer 333 is provided with a second electrode 3331. The second electrode 3331 of each LED die 33 is electrically connected to the first electrode 3311 of another LED die 33 via a metal layer 35, in such a way that these LED dies 33 may be connected in series to be the LED array 300. In addition, the metal layer 35 is deposited on the exposed surface at the side of the second semiconductor layer 333 by means of deposition process similarly.

The substrate 31 is further provided on the surface thereof with a first potential pad 311 and a second potential pad 313. The first potential pad 311 may be also a ground potential pad, while the second potential pad 313 may be also a power-supply potential pad. In the embodiment of the present invention, the first electrode 3311 of the first semiconductor layer 331 stacked lowermost may be connected to the first potential pad 311 of the substrate 31 via a metal wire 371, while the second electrode 3331 of the second semiconductor layer 333 stacked uppermost may be connected to the second potential pad 313 of the substrate 31 via another metal wire 373. The LED array 300 may be then driven for luminescence by power-supply transmitted via the first potential pad 311 and the second potential pad 313 of the substrate 31.

In this case, the manufacturing process adopted by the present invention includes depositingly stacking semiconductor layers 331,333 for manufacturing a plurality of LED dies 33 onto the substrate 31 vertically upward in turn, so as to form the LED array 300 on the substrate 31. Thereby, not only the LED array 300 may be manufactured easily with an effectively reduced volume for arranging the whole LED array 300, but also more LED dies 33 may be provided in a space.

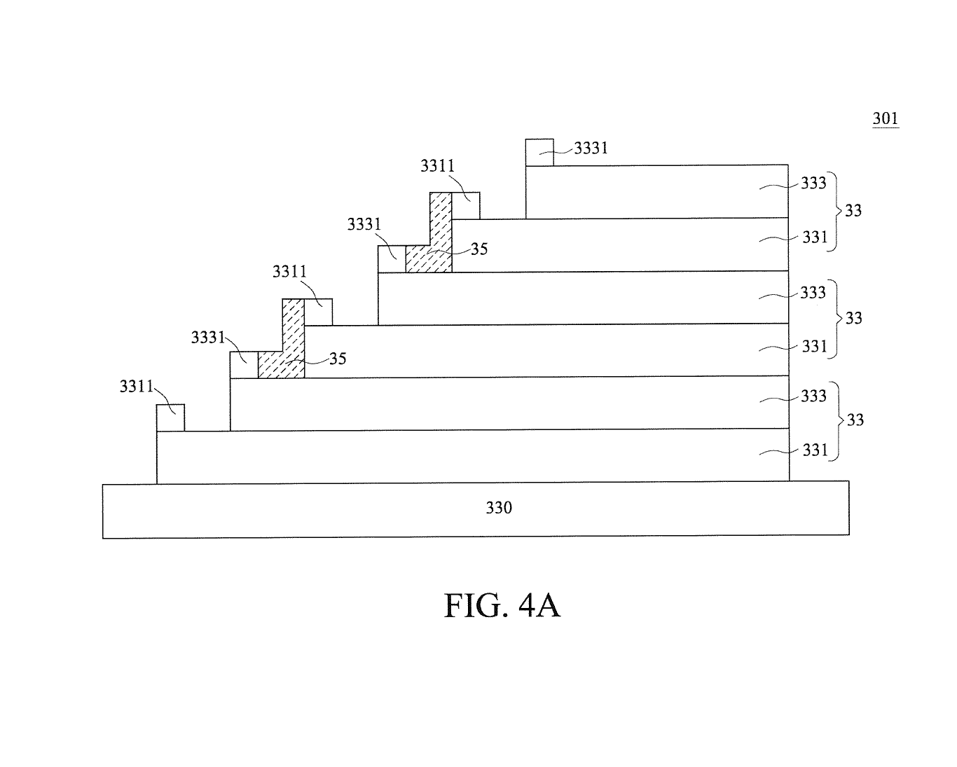

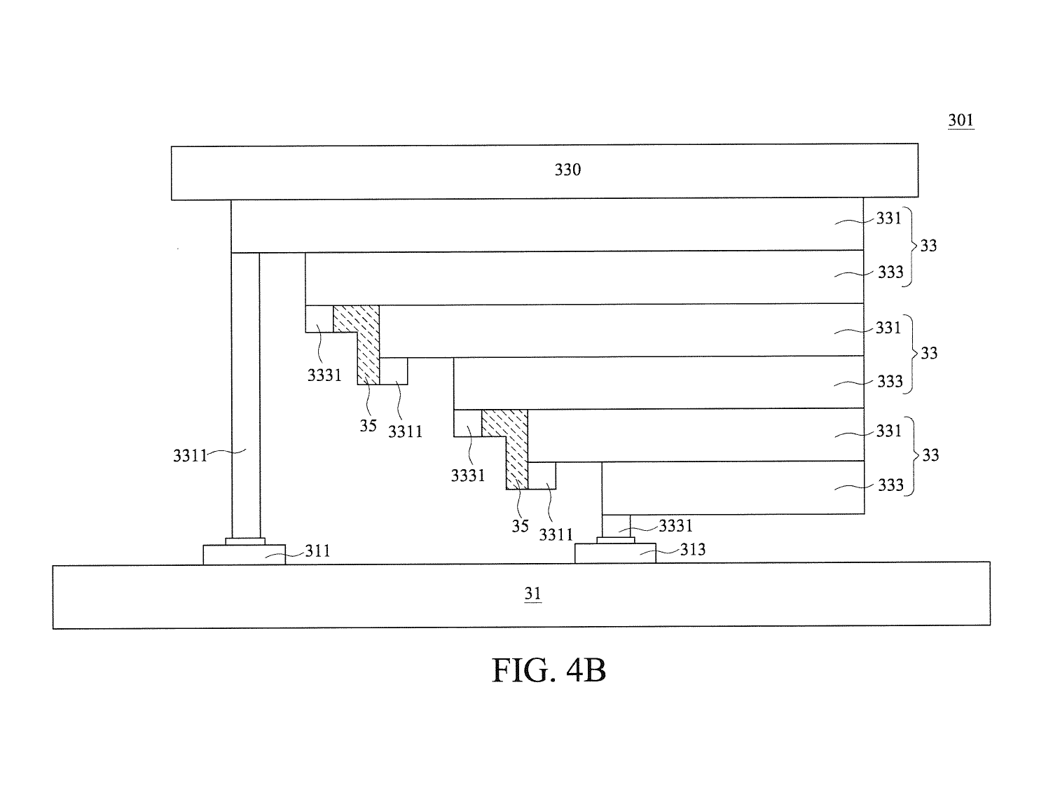

Referring to FIGS. 4A to 4B, there are shown structural diagrams illustrating the manufacturing process of a stacked LED array structure according to a further embodiment of the present invention. In the above embodiment, the LED array 300 is electrically joined to the first potential pad 311 and the second potential pad 313 of the substrate 31 in a wire bonding manner (such as the metal wires 371, 373, for example). In the present embodiment, instead, an LED array 301 is electrically joined to the first potential pad 311 and the second potential pad 313 of the substrate 31 in a flip-chip manner.

As illustrated in FIG. 4A, firstly, the plurality of LED dies 33 may be stacked on a transparent base 330, so as to form the LED array 301 on the base 330. Subsequently, as illustrated in FIG. 4B, the LED array 301 is turned over after the LED array 301 is formed, in such a way that the first electrode 3311 of first semiconductor layer 331 stacked lowermost is joined to the first potential pad 311 of the substrate 31 by means of the bump, while the second electrode 3331 of the second semiconductor layer 333 stacked uppermost is joined to the second potential pad 313 of the substrate 31 by means of the bump.

The stacked LED array 301 of the present invention is then provided on the substrate 31 in a flip-chip manner. Therefore, the stability of electrical connection between the LED array 301 and the substrate 31 may be enhanced.

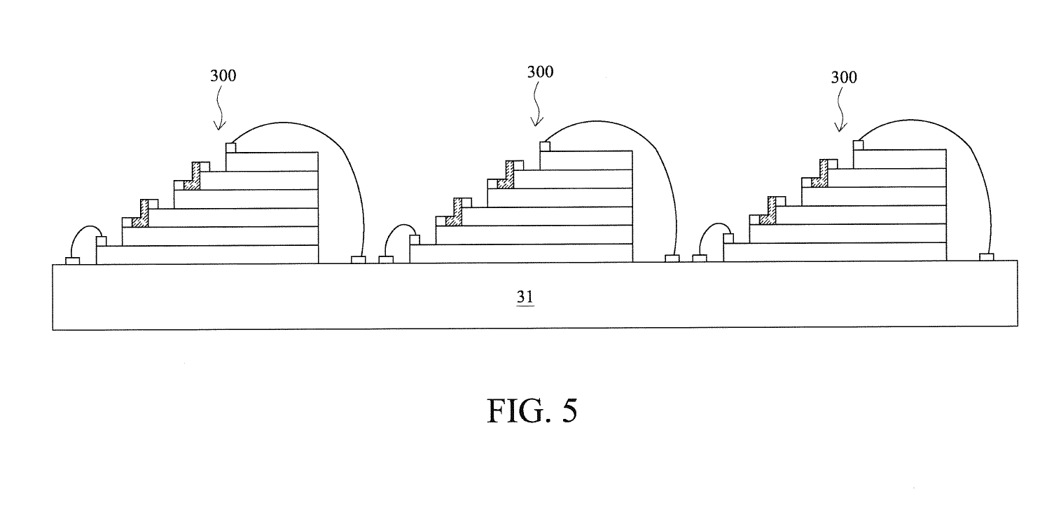

Referring to FIG. 5, there is shown a structural diagram of a stacked LED array structure according to a further embodiment of the present invention. As illustrated in the figure, a plurality of sets of the stacked LED arrays 300 may be provided on the substrate 31 laterally in a wire bonding manner.

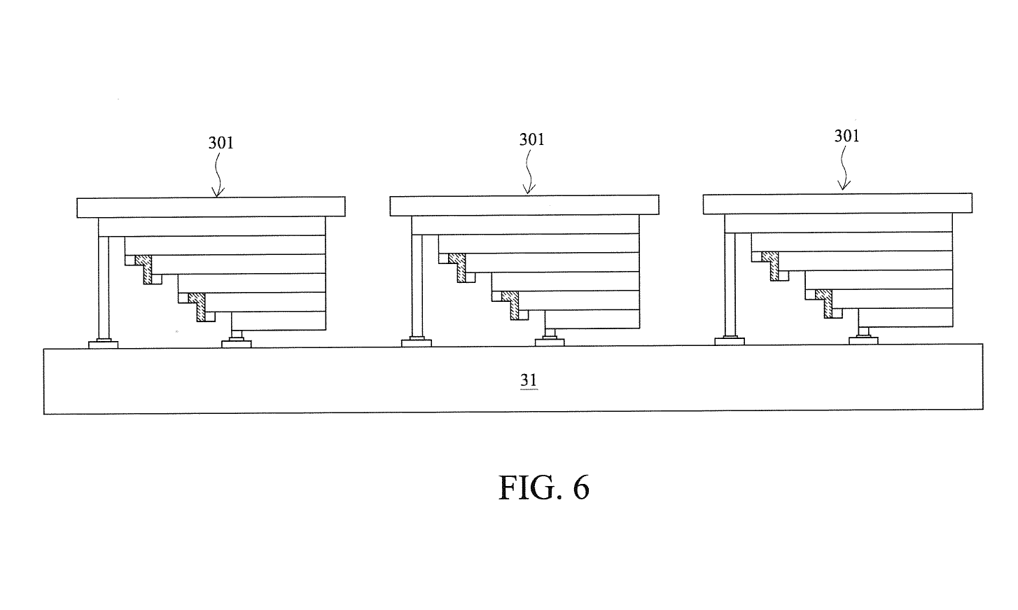

Alternatively, referring to FIG. 6, there is shown a structural diagram of a stacked LED array structure according to a further embodiment of the present invention. As illustrated in the figure, a plurality of sets of the stacked LED arrays 301 may be provided on the substrate 31 laterally in a flip-chip manner.

In this case, when the present invention is applied to illumination, a wider luminescence region together with enhanced luminescence intensity in the region may be obtained, due to the provision of a plurality of sets of the stacked LED arrays 300/301 on the substrate.

Naturally, there are still various embodiments for the present invention. It should be understood that various changes and alterations could be made to the present invention by those skilled in the art without departing from the spirit and scope of the invention, and included within the scope of the appended claims.

1. A stacked LED array structure, comprising:
a substrate, provided on a surface thereof with a first potential pad and a second potential pad;
a plurality of LED dies, stacked on said substrate in turn, each of said LED dies, respectively, comprising:
a first semiconductor layer; and
a second semiconductor layer, in which a top surface of said first semiconductor layer is provided with a first electrode and stacked with said second semiconductor layer, while a top surface of said second semiconductor layer is provided with a second electrode and/or stacked with said first semiconductor layer of another LED die; and
at least one metal layer, in which said second electrode of each of said LED dies is connected to said first electrode of another LED die in series via said corresponding metal layer to be an LED array;
wherein said first electrode of said first semiconductor layer stacked lowermost is connected to said first potential pad of said substrate via a metal wire, while said second electrode of said second semiconductor layer stacked uppermost is connected to said second potential pad of said substrate via another metal wire.

2. The stacked LED array structure according to claim 1, wherein said first semiconductor layer is an N-type semiconductor layer, while said second semiconductor layer is a P-type semiconductor layer.

3. The stacked LED array structure according to claim 1, wherein said substrate is provided laterally thereon with a plurality of sets of said stacked LED arrays.

4. A stacked LED array structure, comprising:
a substrate, provided on a surface thereof with a first potential pad and a second potential pad;
a plurality of LED dies, stacked on a base in turn, each of said LED dies, respectively, comprising:
a first semiconductor layer; and
a second semiconductor layer, in which a top surface of said first semiconductor layer is provided with a first electrode and stacked with said second semiconductor layer, while a top surface of said second semiconductor layer is provided with a second electrode and/or stacked with a first semiconductor layer of another LED die; and
at least one metal layer, in which said second electrode of each of said LED dies is connected to said first electrode of another LED die in series via said corresponding metal layer to be an LED array;
wherein said LED array is provided on said substrate in a flip-chip manner, such that said first electrode of said first semiconductor layer stacked lowermost is connected to said first potential pad of said substrate, while said second electrode of said second semiconductor layer stacked uppermost is connected to said second potential pad of said substrate.

5. The stacked LED array structure according to claim 4, wherein said first semiconductor layer is an N-type semiconductor layer, while said second semiconductor layer is a P-type semiconductor layer.

6. The stacked LED array structure according to claim 4, wherein said substrate is provided laterally thereon with a plurality of sets of said stacked LED arrays.
